(19) United States
(12) Patent Application Publication
(10) Pub. No.: US 2019/0353711 A1
(43) Pub. Date: Nov. 21, 2019

(54) PREDICTING REMAINING USEFUL LIFE OF A BATTERY

(71) Applicant: CW Professional Services LLC d/b/a Lochbridge, Detroit, MI (US)

(72) Inventor: Renjith Paulose, Kerala (IN)

(21) Appl. No.: 16/038,175

(22) Filed: Jul. 17, 2018

(30) Foreign Application Priority Data
May 17, 2018 (IN) 201841018431

(51) Int. Cl. G01R 31/36; H01M 10/42

(52) U.S. Cl. CPC G01R 31/3679; G01R 31/3634; H01M 2010/4271; G01R 31/361; H01M 10/425; G01R 31/3651

(57) ABSTRACT

A system for determining remaining useful life of a battery and method of using the system. The system may include a computer which includes at least one processor and memory. The processor may execute instructions stored on the memory to determine a remaining useful life. In at least one example, based on actual data received, the computer may predict charge capacity of the battery and compare the predicted charge capacity with a threshold charge capacity to determine the remaining useful life.

### CROSS-REFERENCE TO RELATED APPLICATIONS

This patent application claims priority to and all the benefits of Indian Provisional Patent Application No. 201841018431, filed on May 17, 2018, entitled “PREDICTING REMAINING USEFUL LIFE OF A BATTERY,” incorporated herein by reference in its entirety.

### BACKGROUND

A charge capacity of a rechargeable battery can degrade over time. When the potential charge capacity reaches a value in which its relative utility is marginal—e.g., a value in which recharging the battery to its current capacity results in an impractical amount of available charge—then the battery is deemed to have reached an end of its useful life. Predicting RUL can be challenging, even for batteries of a common size and configuration.

### BRIEF DESCRIPTION OF THE DRAWINGS

FIG. 1 is an exemplary schematic diagram illustrating a battery, a computer, and a charger.

FIG. 2 is a flow diagram illustrating an example process for predicting a remaining useful life (RUL) of the battery.

FIG. 3 is a graphical depiction of charge capacity versus time.

FIG. 4 is a schematic diagram of training batteries and the computer.

FIG. 5 is another graphical depiction of charge capacity versus time.

FIG. 6 is a flow diagram illustrating another process for predicting RUL.

### DETAILED DESCRIPTION

Various techniques are described for determining a remaining useful life (RUL) of a battery. A system is described below that comprises at least one computer that receives electrical data pertaining to a re-chargeable battery. According to at least one example, the system carries out a method that includes: determining, for a battery, at least two discharge parameters from among a plurality of discharge parameters, wherein the plurality includes: a discharge quantity parameter, a discharge time parameter, a discharge rest-time parameter, and a discharge total-current parameter; using the at least two discharge parameters to derive a multiple linear regression (MLR) model representing capacity degradation (Q_{decay}); and using the model, calculating a remaining useful life (RUL) of the battery.

According to at least one example of the method, the method further comprises: receiving actual discharge parameter data for a portion of a useful life of the battery; and calculating forecasted discharge parameter data using the actual discharge parameter data, wherein the model is based on the forecasted discharge parameter data.

According to at least one example of the method, the method further comprises: using a single linear regression or an exponential smoothing algorithm to determine the forecasted discharge parameter data. According to at least one example of the method, the method further comprises: using the forecasted discharge parameter data to determine a predicted degradation of the battery at time interval (Wᵢ).

According to at least one example of the method, the method further comprises: using the model, determining a plurality of predicted charge capacities (Q_{predicted(i)}) for a plurality of corresponding predicted degradations (Q_{decay(i)}).

According to at least one example of the method, the method further comprises: determining the RUL by comparing a threshold charge capacity (Q_{THR}) with the plurality of predicted charge capacities (Q_{predicted(i)}).

According to at least one example of the method, the method further comprises: determining the RUL when one of the plurality of predicted charge capacities (Q*_{predicted(i)}) is greater than the threshold charge capacity (Q_{THR}) and a subsequent of the predicted charge capacities (Q*_{predicted(i+1)}) is less than or equal to the threshold charge capacity (Q*_{predicted(i)}>Q_{THR} and Q*_{predicted(i+1)}≤Q_{THR}).

According to at least one example of the method, the RUL comprises a difference between a time of calculation (i_{current}) and a time (i_{future}) that corresponds with Q*_{predicted(i)}.

According to at least one example of the method, the model is based on each of the plurality of discharge parameters.

According to at least one example of the method, the discharge quantity parameter is a quantity (k) of discharge events during a given time interval (Wᵢ).

According to at least one example of the method, the discharge time parameter is an average duration (t_{DE}) of all discharge events for a given time interval (Wᵢ).

According to at least one example of the method, the quiescent-discharge-time parameter is an average duration (t_{QE}) of quiescent events for a given time interval (Wᵢ).

According to at least one example of the method, the discharge total-current parameter is a magnitude of total electrical current (I_{DE}) during a discharge event over a given time interval (Wᵢ).

According to at least one example of the method, the model includes: Q_{decay}=β₀+β₁*Xₖ+β₂*X_{DE}+β₃*X_{QE}+β₄*X_{I}, wherein Xₖ, X_{DE}, X_{QE}, and X_{I} are variables representing the discharge quantity parameter, the discharge time parameter, the quiescent-discharge-time parameter, and the discharge total-current parameter, wherein β₀, β₁, β₂, β₃, and β₄, are calculated constants.

According to at least one example of the method, the battery is a training battery.

According to at least one example of the method, the method further comprises: using the model to determine the RUL of another battery before its useful life expires.

According to at least one other example, the system carries out a method that includes: for a battery, using a plurality of previously-measured charge capacities (Q_{MAX}) and a plurality of corresponding time values, calculating a forecasted charge capacity; and using a threshold charge capacity (Q_{THR}), determining a remaining useful life (RUL) of the battery based on the forecasted charge capacity, wherein the calculation includes using at least one of an exponential smoothing algorithm or an autoregressive model.

According to at least one example of the method, the algorithm is a Holt-Winter exponential smoothing algorithm, wherein the model comprises an Autoregressive Integrated Moving Average (ARIMA).

According to at least one additional example, the system carries out a method that includes: using at least a discharge quantity parameter and a discharge total-current parameter, deriving a multiple linear regression (MLR) model to predict capacity degradation of a rechargeable battery; determining forecasted discharge parameters for each of the discharge quantity and discharge total-current parameters; determining predicted degradation (Q_{decay}) of the battery using the model and the forecasted discharge parameters; and based on the predicted degradation, determining a remaining useful life (RUL) of the battery by comparing the degradation with a threshold charge capacity (Q_{THR}).

According to at least one example of the method, the method further comprises: also using a discharge time parameter and a quiescent-discharge-time parameter to derive the model; and determining the forecasted discharge parameters also using the discharge time and quiescent-discharge-time parameters.

With reference to the figures, wherein like numerals indicate similar or identical features and/or functions throughout the several views, a battery-operated system 10 is shown. The system 10 may comprise a rechargeable battery 12 used to power a load 14 and a computer 20 that comprises one or more processors 22 capable of executing software instructions stored in memory 24 thereof. The battery 12 repeatedly may be: charged to an initial charge capacity using a charger 26 and then discharged to power load 14. Over time, charge capacity of the battery 12 may diminish. During this charging and discharging, computer 20 may receive discharge parameter data associated with the battery 12 and ultimately determine a prediction regarding its remaining useful life. As used herein, a remaining useful life (RUL) of battery 12 is an estimated time quantity in which the battery 12 is capable of being charged only up to a threshold charge capacity (Q_{THR}) or less. As used herein, to retain a charge capacity means that the battery 12—absent a load drawing current therefrom—can retain electrical charge for a threshold amount of time. As will be described more below, the data received by computer 20 may include discharge parameters such as: a discharge quantity parameter, a discharge time parameter, a quiescent-discharge-time parameter, and a discharge total-current parameter. According to at least one embodiment, computer 20 may use discharge parameter data to formulate a multiple linear regression (MLR) model tailored to the performance characteristics of the particular battery 12. Thereafter, computer 20 may use the model to predict a remaining useful life (RUL). These and other techniques will be described below.

Given two identical batteries whose use initiate at the same time, it will be appreciated that different environments and/or different uses of the identical batteries may degrade the charge capacity of batteries at different rates. For example, at a future instant in time, the RUL of one of the batteries may differ from the RUL of the other. For instance, in a Smart phone implementation, one user primarily may expose a first of these batteries to extreme heat and/or regularly drain the battery to 5%. The second of these batteries may remain predominantly within room temperature, and only sporadically be removed from a charger (e.g., thereby rarely decreasing charge to less than 50%). All other environmental aspects and uses being equal, a subsequent instant in time, the RUL of the first battery may be less than that of the second (i.e., the first battery charge capacity may degrade faster than that of the second). According to one example, the techniques described herein may predict the RUL for identical batteries that are used in diverse circumstances. Of course, as explained more below, system 10 may be a Smartphone; however, it may include numerous other implementations as well.

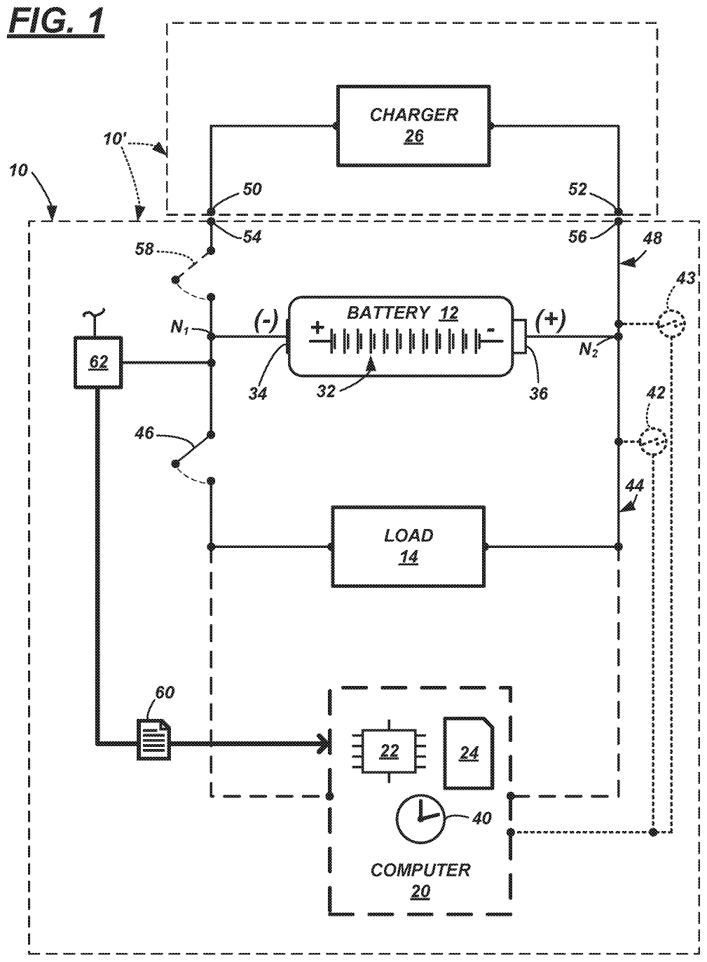

The battery-operated system 10 (shown in FIG. 1) may be any suitable electronic device which comprises one or more rechargeable batteries 12 and one or more loads 14 (e.g., the load 14 is shown as a single load; however, multiple loads arranged in series, parallel, etc. are also contemplated). Further, power of system 10 need not be exclusively battery-operated—e.g., system 10 may be defined by any electronic (or electro-mechanical) device which utilizes—at least intermittently—power from one or more batteries 12. Non-limiting examples of system 10 include portable electronic devices (e.g., such as cellular phones, Smart phones, laptop computers, tablet computers, digital cameras, camcorders, electronic cigarettes, handheld gaming consoles and controllers, flashlights and other handheld lamps), power tools (e.g., such as cordless drills, sanders, saws; and cordless garden trimmers and edgers), and at least partially electric vehicles (e.g., such as automotive vehicles, aircraft, wheelchairs, remote-controlled (RC) model crafts, bicycles, spacecraft and NASA rovers), just to name a few examples.

System 10 may comprise any suitable quantity of batteries 12, which may be arranged in any suitable manner. According to one example, each of the rechargeable batteries may be identical; thus, for purposes of illustration and explanation, only one is described and shown in FIG. 1. According to at least one example, battery 12 is a Lithium-Ion (LI) battery; however, any other suitable type of rechargeable battery can be used instead (e.g., including but not limited to Nickel-Cadmium, Nickel-Metal Hydride, Magnesium-Ion, Nickel-Iron, and Potassium-Ion, just to name a few).

In at least some examples, rechargeable battery 12 may comprise one or more electrochemical cells 32 coupled (e.g., in series and/or in parallel) to an anode 34 (a negative terminal) and a cathode 36 (e.g., a positive terminal). During a discharge event (DE) (e.g., according to a so-called conventional current theory), electrons (e.g., or Lithium ions) move from the anode 34 to the cathode 36 (as used herein, a discharge event means a total electrical charge of battery 12 is decreasing due to current draw by load 14). During a discharge event (DE), current draw may be a nominal magnitude or may float within a predetermined range. And during a charge event, electrons (e.g., or Lithium ions) move from the cathode 36 to the anode 34 (as used herein, a charge event means a total electrical charge of battery 12 is increasing, approaching a charge capacity—e.g., charged by charger 26). As used herein, a charge capacity means a total electrical charge that the battery 12 may carry; note: skilled artisans will appreciate that charge capacity may degrade over the life of the battery 12.

Following a discharge event or a charge event, battery 12 may experience a quiescent event (QE) (also referred to as a rest event). During quiescent events, so-called trickle losses (also referred to as quiescent current) also may decrease total electrical charge of battery 12—e.g., these losses may occur due to background systems operating when load 14 is not drawing current, due to circuit element draw when the load 14 is not drawing current, etc. Typically, trickle losses represent 0-5% of a current draw of load 14; however, other quantities are possible. Accordingly, in at least one example, a quiescent event may comprise zero losses (or zero current draw), at least for a portion of the event. Over enough time, one or more quiescent events (QEs) can degrade the charge capacity of battery 12. As used herein, a quiescent event is one in which no load 14 is connected to battery 12, or one in which load 14—though connected—is not drawing more than 5% of its nominal current from battery 12).

Turning now to load 14 in FIG. 1, the load is shown coupled in parallel to battery 12; however, this is merely an example. As used herein, load 14 is any suitable electrical component or portion of an electrical circuit (e.g., of system 10) that draws current (and thus, consumes electric power) from the rechargeable battery 12 during a discharge or quiescent event. Non-limiting examples of load 14, with respect to the exemplary portable electronic devices listed above, include processors, electronic control circuitry, displays, camera cores, light sources, and the like. Non-limiting examples of load 14, with respect to the exemplary power tools listed above, include processors, electronic control circuitry, brushed or brushless motors, and the like. Non-limiting examples of load 14, with respect to the exemplary vehicles listed above, include processors, electronic control units or modules, powertrain systems, power window and door systems, instrumental panel systems, interior and exterior lighting systems, climate control systems, and the like.

Turning now to computer 20 (FIG. 1), computer 20 may be any suitable computing device which is programmed to receive discharge parameter data and determine a remaining useful life (RUL) of battery 12. Computer 20 may be a stand-alone computer (e.g., connected to a network or not), or it may be part of a larger system of computers or network of computers (neither are shown). In some examples, computer 20 is or includes an electronic control unit (ECU) which performs tasks, in addition to RUL prediction; e.g., computer 20 may be embedded within system 10.

Computer 20 may comprise the at least one processor 22 and memory 24 (e.g., a non-transitory, computer-readable storage medium). Processor 22 may be programmed to process and/or execute digital instructions to carry out at least some of the tasks described herein. Non-limiting examples of processor 22 include a microprocessor, a microcontroller or controller, an application specific integrated circuit (ASIC), or a field-programmable gate array (FPGA). In other examples, processor 22 may comprise an electrical processing circuit—comprising or not comprising a microprocessor, ASIC, FPGA, or the like—the circuit configured to determine or execute one or more system tasks (as used herein, an electrical processing circuit comprises one or more connected circuit elements, arranged to receive an input (e.g., having at least one input node) and arranged to provide an output (e.g., having at least one output node). And a few non-limiting examples of digitally-stored instructions—storable in memory 24 and executable by processor 22—include, to: receive discharge parameter data associated with battery 12; using the discharge parameter data, determine a multiple linear regression (MLR) model; and using the model, predict an RUL for the battery 12. As used herein, discharge parameter data is information used to measure and/or calculate include any combination of one or more of the following: a discharge quantity parameter, a discharge time parameter, a quiescent-discharge-time parameter, and a discharge total-current parameter. Additional and more specific examples of instructions which may be used instead of and/or in addition to these examples, as well as sequences of instructions, are described in the one or more processes below. In at least one example, computer 20 executes a computer program product stored on a non-transitory computer-readable storage medium (e.g., of memory 24). As used herein, a computer program product means a set of instructions (e.g., also called code).

Memory 24 may include any non-transitory computer usable or readable medium, which may include one or more storage devices or articles. Exemplary non-transitory computer usable storage devices include conventional hard disk, solid-state memory, random access memory (RAM), read-only memory (ROM), erasable programmable read-only memory (EPROM), electrically erasable programmable read-only memory (EEPROM), as well as any other volatile or non-volatile media. Non-volatile media include, for example, optical or magnetic disks and other persistent memory, and volatile media, for example, also may include dynamic random-access memory (DRAM). These storage devices are non-limiting examples; e.g., other forms of computer-readable media exist and include magnetic media, compact disc ROM (CD-ROMs), digital video disc (DVDs), other optical media, any suitable memory chip or cartridge, or any other medium from which a computer can read. As discussed above, memory 24 may store one or more computer program products which may be embodied as software, firmware, or other programming instructions executable by the processor 22.

In at least one example, computer 20 further comprises a timer 40. As used herein, timer 40 comprises an electrical or electro-mechanical timing circuit (or circuit element) configured to measure time (a hardware implementation), a set of instructions executable by processor 22 which enable computer 20 to measure time (a software implementation), or a combination thereof. For example, an electrical or electro-mechanical timing circuit may comprise one or more electrical components such as a timer or clocking integrated chip (IC), an oscillator, or the like. And for example, a timer implemented using software instructions may comprise a plurality of instructions for measuring time between events, determining a start time and/or an end time of a discharge, a charge, or a quiescent event, etc. As will described more below, timer 40 may be used: to determine a discharge quantity parameter (e.g., to determine a quantity of discharge cycles within a time interval), to determine a discharge time parameter (e.g., to determine an average discharge time for a plurality of discharge/charge cycles within the time interval), and to determine a quiescent-discharge-time parameter (e.g., to determine an average of all time of all quiescent events within the time interval).

In at least one example, system 10 and/or computer 20 comprise one or more electrical meters 42, 43. Two are shown by way of example; however, different quantities may be used. Meter 42 may measure current, voltage, power, etc. delivered from or charged to battery 12. For example, FIG. 1 illustrates meter 42 connected to a circuit loop 44 that comprises the battery 12, load 14, and an optional switch 46 (shown in an open position). When the switch 46 is in a closed position, load 14 may draw current via loop 44 and meter 42 may measure instantaneous, average, and/or total current. According to at least one example, meter 42 may be used with timer 40 to determine a discharge total-current parameter (e.g., a summation of total current discharged during a plurality of cycles within the time interval discussed above (as used herein, a cycle means at least one charge event and at least one subsequent discharge event; a cycle may comprise zero, one or multiple quiescent events interspersed before and/or after the charge and discharge event within the cycle)).

In another example shown in FIG. 1, optional meter 43 may be connected to a circuit loop 48 which comprises the battery 12, and when coupled, charger 26. Meter 43 similarly may be used with timer 40 to measure current, voltage, power, etc.—here, during a charge event.

System 10 may be coupled by wire or wirelessly with charger 26 so that battery 12 may be charged. For example, FIG. 1 illustrates that charger 26, via terminals 50, 52, may be coupled by wire to terminals 54 and 56 (of system 10), respectively, so that charger 26 is arranged in parallel with battery 12 and part of circuit loop 48. As used herein, a charger is any device configured to deliver electrical charge to charge battery 12. Non-limiting examples of charger 26 comprise a generator (e.g., a device that converts mechanical energy into electrical power—e.g., such as an alternator or the like), any AC-DC charger (e.g., any device that converts alternating current (AC) power into direct current (DC) power), a DC-DC charger (e.g., any device that converts DC power (e.g., at a first voltage) up or down to DC power (e.g., at a second voltage)), an inductive charger (e.g., inducing charge current delivered to battery 12), or the like. Further, charger 26 may comprise a wired or wireless charge connection. These are all merely examples; other charger implementations also exist.

Thus, according to some examples, charger 26 is separate from, but couplable to system 10. Non-limiting examples include portable electronic devices (e.g., such as Smart phones, laptop and tablet computers, gaming controllers, etc.), as well as in a number of power tool examples (e.g., including handheld drills, sanders, trimmers, etc.), as well as in several vehicle examples (e.g., wheelchairs, remote-controlled crafts, etc.). Other examples exist.

In at least one example, charger 26 delivers electrical charge to battery 12 when an optional switch 58 is in a closed position. As discussed below, switch 58 may be useful when the charger 26 forms part of the system (e.g., a system 10′).

Accordingly, in at least one example, charger 26 is part of the system (e.g., system 10′ comprising charger 26, battery 12, and load 14—as well as computer 20 in some examples). For example, in some vehicle implementations, the computer 20 may be part of a power management system (e.g., responsible for delivering and controlling electrical power to the powertrain, lighting systems, vehicle electronics, etc.), while the charger 40 may be onboard as well (e.g., generating or recapturing charge via vehicle braking or the like). Again, this is merely an example of system 10′; other examples also exist.

In the example described above (FIG. 1), computer 20 may directly monitor discharge parameter data—e.g., being coupled to battery 12 (and/or load 14 and/or charger 26) and being coupled to and using timer 40, meter 42 and/or 43, etc. As used herein, directly monitoring means monitoring discharge parameter data while battery 12 experiences charge, discharge, and/or quiescent events. In other examples, computer 20 may receive the discharge parameter data following a series of charge, discharge, and/or quiescent events (e.g., referred to herein as indirectly monitoring). For example, computer 20 may receive a data log via an on-board system processor (not shown) having memory that stores discharge parameter data and permits a file 60 download (of charge, discharge, and/or quiescent events) via a communication port 62—e.g., when computer 20 is coupled thereto. Port 62 may permit download via any suitable protocol or means; non-limiting examples include, via: USB, Ethernet, Firewire, serial data transfer (e.g., RS-232, RS-422, etc.), or the like.

Furthermore, in at least one example, while not shown here, computer 20 may selectively control charge and/or discharge events. For example, computer 20 selectively may operate switches 46 and/or 58—e.g., determining when to charge battery 12 and when to permit load 14 to discharge battery 12. Computer 20 may control an alternate switching pattern so that discharge events are distinct from charge events. In some examples, computer 20 further may control the timing of quiescent events as well. Of course, an alternating switching pattern is merely one example; other examples exist as well.

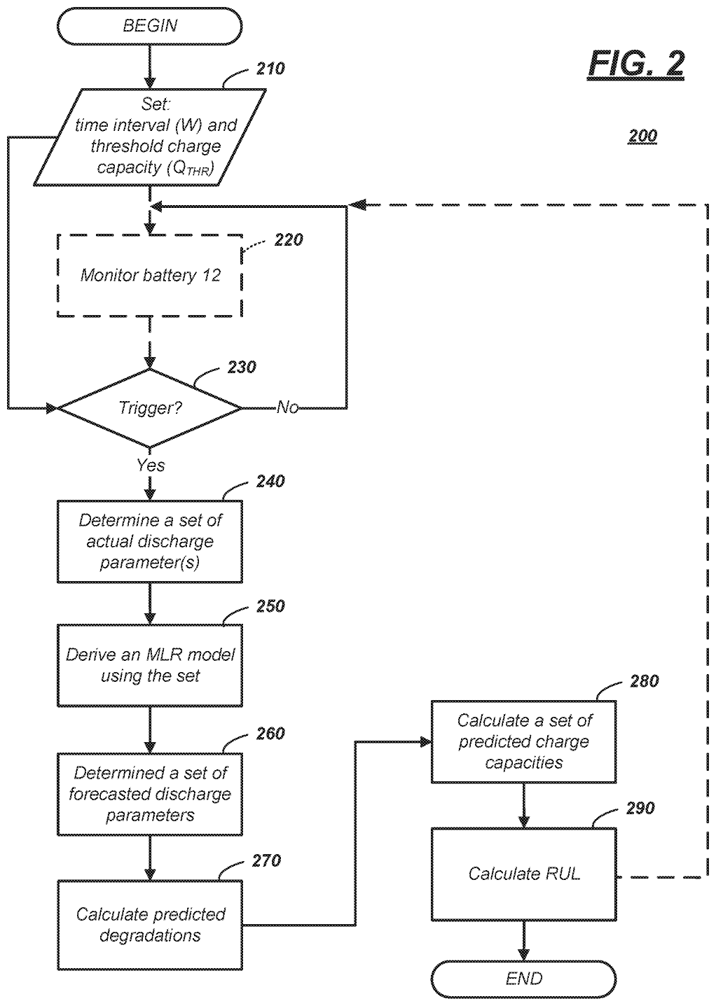

Turning now to FIG. 2, a process 200 is shown for predicting a remaining useful life (RUL) of battery 12. The process begins with block 210, wherein computer 20 may store in memory 24 a value for a predetermined time interval W. The time interval W may represent a week, a month, a predetermined number of days, or the like. According to the illustration below, the time interval W is one week.

In block 210, memory 24 also may store a predetermined threshold charge capacity (Q_{THR}) as well. Recall that the threshold charge capacity (Q_{THR}) is a value at which, when the battery's maximum charge capacity equals Q_{THR}, then the battery 12 is considered to be at the end of its useful life. Thus, as described below, a comparison of the battery's maximum current charge capacity (Q_{MAX}) to its threshold charge capacity (Q_{THR}) may be used to determine the battery's RUL. By way of example only, and not intending to be limiting, if an initial charge capacity (Q₀) (e.g., off-the-shelf) of battery 12 may be 2.1 Amp-hours (Ah) and the battery's threshold charge capacity (Q_{THR}) is considered to be 1.2 Ah, then battery 12 is considered within its useful life until its current charge capacity (Q_{MAX}) becomes less than or equal to the threshold charge capacity (Q_{THR}) (e.g., drops below 1.2 Ah). For example, typically, the battery's current charge capacity (Q_{MAX}) will decay over time—e.g., decreasing from 2.1 Ah to 2.0 Ah, from 2.0 Ah to 1.9 Ah, . . . , to 1.2 Ah; i.e., until its maximum current charge capacity (Q_{MAX}) is the same as or less than the threshold charge capacity (Q_{THR}).

Following block 210, computer 20 may directly monitor battery 12, receiving (and storing in memory 24) discharge parameter data (block 220)—e.g., receiving actual discharge parameter data during at least a portion of the useful life of battery 12 (e.g., before the battery 12 expires). This block is optional, and alternatively, process 200 may proceed from block 210 to block 230. For example, as discussed above, computer 20 instead could receive from other electronics of system 10 (and store in memory 24) one or more files 60 that comprise discharge parameter data (for a plurality of time intervals).

According to one example of block 220, computer 20 identifies a start-time of a reference charge event, and then monitors and receives discharge parameter data, from battery 12, until an end-time of a reference discharge event is identified by computer 20 (e.g., the discharge parameter data is received for a plurality of cycles). As used herein, a time interval is defined herein as a plurality of cycles and/or a predetermined time period. For example, the time interval may be a duration spanning between the start-time of the reference charge event and the end-time of the reference discharge event. Or for example, the time interval may be a predetermined time period such as approximately one week (or 168 hours, e.g., +/−1 hour). Of course, time intervals other than week increments may be used instead. According to at least some examples, the time intervals have the same duration.

Table I, which will be explained in greater detail below, illustrates a period of eight illustrative time intervals (e.g., Wᵢ, wherein i=1, 2, . . . , 8); of course, a quantity of eight is merely an example. In at least some examples, the start-time corresponds with a first commercial use of battery 12 (e.g., at the outset of the time interval W₁). In at least one example, the quantity of time intervals monitored by computer 20 is predetermined based on characteristics of the battery 12—e.g., for some batteries, the quantity (i) of intervals (or total duration of monitored discharge parameter data) may be eight weeks; for other batteries the quantity (i) of intervals (or total duration of monitored discharge parameter data) may be ten weeks; and for other batteries, the quantity (i) of intervals (or total duration of monitored discharge parameter data) may be sixteen weeks, etc. These are examples; other durations may be used instead.

In general, the quantity of monitored time intervals should be sufficient for computer 20 to derive statistically a multiple linear regression model, as explained more below. For example, too few time intervals may provide insufficient data for the model to provide an accurate estimation. For example, a minimum of five time intervals may be desirable.

TABLE I

| | | | Quiescent- | Discharge |
|---|---|---|---|---|
| | Discharge | Discharge | discharge- | Total- |
| | Quantity | Time | time | current |
| Wᵢ | parameter | parameter | parameter | parameter |
| i = 1 | 955 | 29.035 | 0.3005 | 196949.387 |
| i = 2 | 985 | 29.038 | 0.2963 | 199602.297 |
| i = 3 | 973 | 28.967 | 0.3372 | 192617.38 |
| i = 4 | 878 | 28.8132 | 0.2771 | 176281.301 |
| i = 5 | 832 | 28.8778 | 0.2745 | 162079.866 |
| i = 6 | 762 | 28.8067 | 0.2499 | 154037.578 |
| i = 7 | 759 | 28.7737 | 0.2661 | 150684.488 |
| i = 8 | 750 | 28.6725 | 0.2875 | 146464.294 |

The discharge parameter data in Table I is exemplary data for a lithium-ion battery. It is intended to be used to illustrate process 200 and is not intended to be limiting. Accordingly, process 200 may be executed using a lithium-ion battery; however, battery 12 could have cells other than lithium-ion.

Following at least some monitoring in block 220, computer 20 may execute block 230 by determining whether a trigger has occurred. According to one example, an instantaneous measure of time is received from timer 42, and computer 20 determines whether the instantaneous measure matches (or exceeds) the trigger. If the trigger is determined, process 200 proceeds to block 240. And if computer 20 does not determine the trigger, then the process loops back and repeats blocks 220-230 until the trigger is determined. It should be appreciated that discharge parameter data (or parameters derived therefrom as shown in Table I) may be stored incrementally at computer 20 when the computer 20 is directly monitoring battery 12. Accordingly, if no trigger is yet determined in block 230, then computer 20 may continue to receive discharge parameter data.

Continuing with the example above, computer 20 may determine whether the measurement from timer 42 corresponds with a predetermined trigger value—e.g., such as a duration of eight weeks (see Table I). Thus, timer 42 may measure from a start-time (of one charge event) to an end-time (of a discharge event), and if the duration measured by timer 42 therebetween matches or exceeds a trigger value stored in memory 24, computer 20 determines the trigger and proceeds to block 240. And if the predetermined trigger value (e.g., a duration of eight weeks) has not been reached, then computer 20 may loop back and continue to monitor discharge parameter data in block 220.

In another example, the trigger in block 230 is associated with computer 20 desiring to determine an instantaneous RUL. For example, another computing device (or a user of system 10) may query: ‘what is the RUL of battery 12?’ Thus, such a query itself may be the trigger in at least some examples. It should be appreciated that in this example, an accuracy of the predicted RUL may depend upon the quantity of actual discharge parameter data—e.g., a larger quantity of time intervals (of actual discharge parameter data) may yield a more accurately predicted RUL.

In the examples of computer 20 indirectly monitoring battery 12, the trigger of block 230 may be computer 20 receiving a file 60 from system 10. In this example, computer 20 may be linked communicatively with an onboard computing device (e.g., a system ECU) which provides it the discharge parameter data (e.g., incrementally or in batches). Further, in some of these instances, computer 20 may be a diagnostic device coupled to but not part of system 10 (e.g., hence it is shown in phantom in FIG. 1). In these cases, as explained more below, computer 20 may determine the MLR model and predict the RUL of battery 12 but may not collect the data from the battery 12 (or its electrical circuit) itself.

In block 240, using the discharge parameter data, computer 20 determines a plurality of actual discharge parameters. As explained below, these actual discharge parameters can be used to determine a plurality of forecasted discharge parameters, which are used to calculate RUL. As used herein, an actual discharge parameter pertains to charge and/or discharge events of battery 12 and is measured discharge parameter data or is discharge parameter data that is both measured and calculated (based on the measurements). And as used herein, a forecasted discharge parameter is one which is estimated (e.g., extrapolated, statistically-determined, etc.) for a future instant in time using one or more actual discharge parameters—i.e., it is not a physical measurement of electrical current, voltage, or the like.

Table I illustrates four illustrative categories of actual discharge parameters: a discharge quantity parameter, a discharge time parameter, a quiescent-discharge-time parameter, and a discharge total-current parameter. How the computer 20 may derive each actual discharge parameter will be discussed in turn. Further, in at least one example of block 240, computer 20 determines a set of actual discharge parameters (e.g., two, three, four, or more of such actual discharge parameter examples). And as will be explained more below, computer 20 may use these actual discharge parameters to develop a multiple linear regression (MLR) model with which it may predict a RUL of battery 12.

Thus, block 240 may comprise computer 20 determining a discharge quantity parameter (e.g., at least one of the set). As used herein, a discharge quantity parameter means a quantity (k) of discharge events during a given time interval (Wᵢ). According to one example, computer 20 may determine an actual discharge quantity parameter by determining a quantity (k) of discharge events each of a plurality of respective time intervals Wᵢ. For example, computer 20 may quantify a number of times switch 46 is opened and closed—e.g., according to a presumption that when switch 46 closes, load 14 is drawing charge from battery 12 (discharge event) and when switch 46 is re-opened, charger 26 is providing a charge to battery 12 (charge event). Thus, computer 20 may count cycles. Alternatively, or in combination therewith, computer 20 may monitor data from meter 42 to determine a quantity (k) of discharge events (e.g., observing changes in voltage or current while counting cycles). Still other techniques are possible. Thus, for purposes of illustration only (according to Table I), computer 20 may record ‘955’ discharge events during time interval W₁. Similarly, computer 20 may record ‘985’ discharge events during time interval W₂. Etc.

Further, block 240 further may comprise computer 20 calculating an actual discharge time parameter. As used herein, a discharge time parameter means an average duration (t_{DE}) of all discharge events (DEs) for a given time interval (Wᵢ). As explained above, computer 20 may use the times the switch 46 is in an open position—and timer 40—to measure each duration. Or computer 20 may a duration when meter 42 indicates a charge. Or it may determine duration in any other suitable manner. Regardless of the measuring technique, computer 20 may average a number (n) of discharge events (t_{DE(1)}, t_{DE(2)}, . . . , t_{DE(n))} for the given interval (Wᵢ), as set forth in Equation (1).

$$Discharge time parameter = \frac{1}{n} * {\sum }_{1}^{n} {t}_{DE ( n )} . \qquad Equation ( 1 )$$

Further, block 240 further may comprise computer 20 calculating an actual quiescent-discharge-time parameter. As used herein, a quiescent-discharge-time parameter means an average duration (t_{QE}) of quiescent events (QEs) for a given time interval (Wᵢ). For example, computer 20 may average a number (m) of quiescent events (t_{QE(1)}, t_{QE(2)}, . . . , t_{QE(m))} for the given interval (Wᵢ), as set forth in Equation (2). To determine quiescent events (QEs), computer 20 may use meters 42 and/or 43, determine positions of switch 46 and/or switch 58 (e.g., both switching in the open position), or the like. Further, computer 20 may utilize timer 40 to measure a duration of any quiescent event.

$$Equation ( 2 )$$

$$Quiescent discharge time parameter = \frac{1}{m} * {\sum }_{1}^{m} {t}_{QE ( m )} .$$

Further, block 240 further may comprise computer 20 calculating an actual discharge total-current parameter. As used herein, a discharge total-current parameter means a magnitude of total electrical current (I_{DE}) during a discharge event (e.g., in milli-amps (mA)) over a given time interval (Wᵢ). For example, using meter 42 (or any other suitable technique), computer 20 may sum measured current during each discharge event for a given interval (Wᵢ), in accordance with Equation (3).

Discharge total−current parameter=Σ₁ⁿI_{DE(n)}, Equation (3).

wherein n is the number of discharge events, for the given time interval (Wᵢ), as determined in Equation (1).

Having determined actual discharge parameters for each of the plurality of discharge parameters and for each of the time intervals (Wᵢ), computer 20 may proceed from block 240 to block 250 and derive an MLR model using the set of actual discharge parameters. The MLR model representing degradation of battery 12 may be calculated using R-software (e.g., such as R-language software utilizing Bayesian statistics, available at “The R Project Statistical Computing,” https://www.r-project.org, last visited Apr. 18, 2018, the contents of which are hereby incorporated by reference in their entirety). See an example of the MLR model in Equation (4).

MLR model: Q_{decay}=β₀+β₁*Xₖ+β₂*X_{DE}+β₃* X_{QE}+β₄*X_{I}+ε, Equation (4)

wherein, Q_{decay} represents a predicted capacity degradation of battery 12, wherein Xₖ, X_{DE}, X_{QE}, and X_{I} respectively represent discharge quantity, discharge time, quiescent-discharge-time, and discharge total-current variables, wherein β₀, β₁, β₂, β₃, and β₄, are statistically-calculated constants unique to the particular MLR model, and wherein ε is deviation (e.g., typically having a negligible value; in this instance, it may be considered to be zero).

In the example above, all four discharge parameters of Table I are used to derive the MLR model; however, as discussed previously, more or fewer discharge parameters may be used in other examples. For example, battery-degradation MLR models could have two variables (and three beta-constants), three variables (and four beta-constants), four different variables (and five beta-constants), and five or more variables (etc.).

In accordance with a Pearson Correlation, a quantity of discharge events within a time interval has a correlation of 0.965 (highly positively correlated) and a discharge total-current within a time interval has a correlation value of 0.966 (highly positively correlated). Also, in accordance with the Pearson Correlation, an average discharge time within a time interval has a correlation of 0.816 (positively correlated), and an average quiescent-discharge-time within a time interval has a correlation of 0.826 (positively correlated). Thus, in one non-limiting example, the MLR model could use only the discharge quantity and discharge total-current variables (e.g., both highly positively correlated parameters). In other example, the MLR model could use only the discharge quantity, the discharge total-current, and one or both of the discharge time or quiescent-discharge-time variables. Other examples exist—some of which may comprise other positively or highly positively correlated variables.

Thus, it should be appreciated that deriving the MLR model may comprise: identifying which discharge parameters will be used (e.g., which X-variables) and then calculating the respective coefficients (e.g., β-values). Using the discharge parameter data of Table I, the model Q_{decay} shown in Equation (4), and suitable R-Software, computer 20 may derive the example MLR model shown in Equation (5). It should be appreciated that this particular MLR model is only an example; using other criteria, more or fewer X-variables may be used and different β-values may be derived. Once a unique MLR model is determined using the set of actual discharge parameters, then computer 20 may determine forecasted discharge parameters which, as described below, can be used as input the MLR model (of Equation (5)).

Example MLR model: Q_{decay}=1.334+0.00004409* Xₖ+(−0.05035)* X_{DE}+0.02283*X_{QE}+0.0000007129*X_{I}. Equation (5).

Accordingly, in block 260 which follows, computer 20 may execute a single linear regression for each of the sets of actual discharge parameters—and thereby calculate respective forecasted discharge parameters. According to at least one example, a sub-process of executing the single linear regression, for each of the discharge parameters, may be identical; therefore, only one example of how the sub-process is executed will be described in detail below (e.g. using the discharge quantity parameter as an example).

Determining a single linear regression of the discharge quantity parameter may include determining a unique slope-intercept formula (Equation (6)) using the set of actual discharge parameters (i.e., in this case, the actual discharge quantity parameters for weeks 1-8). Slope (a) and intercept (b) may be calculated using Equations (7) and (8), shown below.

y_{Dp}=Mx_{Dp}+B, Equation (6).

wherein y_{Dp} represents a dependent value (with respect to a dependent axis) of the discharge parameter linear regression model, wherein x_{Dp} represents an independent value (with respect to an independent axis) of the discharge parameter linear regression model, wherein M represents slope of a unique single linear regression line plotted on the respective independent and dependent axes, wherein B represents an intercept of the single linear regression line with the dependent axis.

$$Slope ( M ) = \frac{{i}_{total} * \sum {X}_{DP} {Y}_{DP} - ( \sum {X}_{DP} ) ( \sum {Y}_{DP} )}{{i}_{total} * \sum {X}_{DP}^{2} - {( \sum {X}_{DP} )}^{2}} , \qquad Equation ( 7 )$$

wherein iₜₒₜₐₗ is a total quantity of evaluated time intervals of actual discharge parameter data (as discussed above) (e.g., continuing with the previous example, a total of ‘8’ time intervals are used), wherein X_{DP} is the respective time interval data (e.g., 1, 2, . . . iₜₒₜₐₗ), wherein X_{DP} is the respective actual discharge parameter data (e.g., continuing with the discharge quantity parameter example, 955, 985, . . . ), wherein ΣX_{DP}Y_{DP} represents a cross product summation, wherein ΣX_{DP} represents a summation of the respective time interval values, wherein ΣY_{Dp} represents a summation of the respective actual discharge parameters, wherein ΣX_{DP}² represents a sum of squares, wherein (ΣX_{DP})² represents a square of the summation.

$$Intercept ( B ) = \frac{\sum {Y}_{DP} - b * \sum {X}_{DP}}{{i}_{total}} . \qquad Equation ( 8 )$$

The value of slope M and the value of intercept B—determined in Equations (7) and (8)—may be used in Equation (6) to generate a unique linear regression equation, such as that set forth in example Equation (9).

Example y_{DP}=38.6190476x_{DP}+1035.535714. Equation (9).

Once this unique linear regression equation is determined (e.g., for the particular discharge parameter), then computer 20 may use the equation to forecast a plurality of forecasted discharge parameters for i₁ through i_{forecasted}, wherein i_{forecasted} refers to the actual and a projected (a.k.a., future) quantity of intervals (e.g., Table II below illustrates forecasted values for the actual time intervals, i₁ through i₈, and future intervals i₉-i₃₀). Thus, continuing with the example above, computer 20 may execute y_{DP}=38.6190476x_{DP}+1035.535714 for all values of Wᵢ (e.g., the independent variable x_{DP}) wherein i: 1→30 and the respective dependent variable values (y_{DP}) are the forecasted discharge time parameter values shown in Table II (e.g., 997, 958, 920, . . . , 31).

It should be appreciated that the forecasted discharge quantity parameter values for i: 1→8 are not identical to the corresponding values shown in Table I, as the values shown in Table II are calculated based on a single linear regression model of Equation (9), whereas those values in Table I are measured (or measured and calculated) values with respect to battery 12 itself.

TABLE II

| | | | Forecasted | | | |
|---|---|---|---|---|---|---|
| | Forecasted | Forecasted | Quiescent- | Forecasted | | |
| | Discharge | Discharge | discharge- | Discharge | | Predicted |
| | Quantity | Time | time | Total-current | Predicted | Charge |
| | parameter | parameter | parameter | parameter | Degradation | Capacity (Ah) |
| Wᵢ | (Xₖ) | (X_{DE}) | (X_{QE}) | (X_{I}) | (Q_{decay}) | (Q_{predicted}) |
| i = l | 997 | 29.051125 | 0.307242 | 202669.805 | 0.06146 | 2.07113 |
| i = 2 | 958 | 29.00022857 | 0.301212 | 194004.024 | 0.06443 | 2.0067 |
| i = 3 | 920 | 28.94933214 | 0.295182 | 185338.244 | 0.06343 | 1.94328 |
| i = 4 | 881 | 28.89843571 | 0.289152 | 176672.464 | 0.05396 | 1.88931 |
| i = 5 | 842 | 28.84753929 | 0.283123 | 168006.684 | 0.0385 | 1.85082 |
| i = 6 | 804 | 28.79664286 | 0.277093 | 159340.904 | 0.0327 | 1.81812 |
| i = 7 | 765 | 28.74574643 | 0.271063 | 150675.123 | 0.03221 | 1.78591 |
| i = 8 | 727 | 28.69485 | 0.265033 | 142009.343 | 0.03439 | 1.75153 |
| i = 9 | 688 | 28.64395357 | 0.259004 | 133343.563 | 0.02308 | 1.72844 |
| i = 10 | 649 | 28.59305714 | 0.252974 | 124677.783 | 0.01761 | 1.71083 |
| i = 11 | 611 | 28.54216071 | 0.246944 | 116012.003 | 0.01218 | 1.69865 |
| i = 12 | 572 | 28.49126429 | 0.240914 | 107346.222 | 0.00671 | 1.69193 |
| i = 13 | 533 | 28.44036786 | 0.234885 | 98680.4422 | 0.00124 | 1.69069 |
| i = 14 | 495 | 28.38947143 | 0.228855 | 90014.662 | 0.00419 | 1.68651 |
| i = 15 | 456 | 28.338575 | 0.222825 | 81348.8818 | 0.00966 | 1.67684 |
| i = 16 | 418 | 28.28767857 | 0.216795 | 72683.1015 | 0.01509 | 1.66175 |
| i = 17 | 379 | 28.23678214 | 0.210765 | 64017.3213 | 0.02056 | 1.64199 |
| i = 18 | 340 | 28.18588571 | 0.204736 | 55351.5411 | 0.02603 | 1.61516 |
| i = 19 | 302 | 28.13498929 | 0.198706 | 46685.7609 | 0.03146 | 1.5837 |
| i = 20 | 263 | 28.08409286 | 0.192676 | 38019.9807 | 0.03694 | 1.54676 |
| i = 21 | 225 | 28.03319643 | 0.186646 | 29354.2005 | 0.04236 | 1.5044 |
| i = 22 | 186 | 27.9823 | 0.180617 | 20688.4203 | 0.04784 | 1.45656 |
| i = 23 | 147 | 27.93140357 | 0.174587 | 12002.6401 | 0.05331 | 1.40325 |
| i = 24 | 109 | 27.88050714 | 0.168557 | 3356.85993 | 0.05874 | 1.34452 |
| i = 25 | 70 | 27.82961071 | 0.162527 | 3356.85993 | 0.05803 | 1.28649 |
| i = 26 | 31 | 27.77871429 | 0.156498 | 3356.85993 | 0.05733 | 1.22916 |
| i = 27 | 31 | 27.72781786 | 0.150468 | 3356.85993 | 0.0549 | 1.17426 |
| i = 28 | 31 | 27.67692143 | 0.144438 | 3356.85993 | 0.05248 | 1.12178 |
| i = 29 | 31 | 27.626025 | 0.138408 | 3356.85993 | 0.05005 | 1.07173 |
| i = 30 | 31 | 27.57512857 | 0.132379 | 3356.85993 | 0.04763 | 1.02411 |

As described above, once forecasted discharge quantity parameters (Xₖ) are determined, computer 20 (using Equations (7) and (8)) may determine single linear regression equations (e.g., Equation (6)) unique to each of the discharge time parameter, the quiescent-discharge-time parameter, and the discharge total-current parameter. Using the derived unique equations for those respective parameters, computer 20 similarly may calculate forecasted discharge parameters (for X_{DE}, X_{QE}, and X_{I}) for i: 1→i_{forecasted}. Thereafter, process 200 may proceed from block 260 to block 270.

In block 270, computer 20 may calculate predicted degradations (Q_{decay}) that correspond to the time intervals (e.g., i: 1→i_{forecasted}). For example, computer 20 may use the unique MLR model (e.g., derived in block 250; e.g., Equation (5)) and the forecasted discharge parameters (e.g., determined in block 260 and derived using unique equations (see Equations (6), (7), and (8)) to calculate the predicted degradations (Q_{decay}). For example, for i=1, computer 20 may calculate Q_{decay(1)}=1.334+0.00004409*997+(−0.05035)*29.051125+0.02283*0.307242+0.0000007129*202669.805=0.06146. Computer 20 may repeat this calculation for values i: 2→i_{forecasted}.

In block 280, computer 20 may calculate maximum predicted charge capacities (Q_{predicted}) using Equation (10), wherein the predicted charge capacities (i.e., Q_{predicted(i)} for a given time interval (Wᵢ) are a difference between a previous [predicted] charge capacity (Q_{predicted(i-1)}) and the predicted degradation (Q_{decay(i)}).

Predicted Charge Capacity (Q_{predicted(i)})=Q_{predicted(i-1)}−Q_{decay(i)}. Equation (10).

To illustrate Equation (10), consider that prior to the first time interval (i=1), the charge capacity is the initial charge capacity (Q₀=2.13259 Ampere hours (Ah)). Further, consider that based on the MLR model (Equation (5)) and the single linear regressions associated with the first time interval (i.e., forecasted discharge parameters Xₖ₍₁₎, X_{DE(1)}, X_{QE(1)}, and X_{I(1)} are 997, 29.051125, 0.307242, and 202669.805, respectively) and the predicted degradation (Q_{decay(1)}).) is 0.06146. Thus, in accordance with Equation (10), (Q_{predicted(1)})=Q_{predicted(0)}−Q_{decay(1)}=2.13259−0.06146=2.07113 Ah.

Similarly, for the second time interval (i =2)—to determine Q_{predicted(2)}, the calculation of Equation (10) may be repeated. For example, (Q_{predicted(2)})=Q_{predicted(1)}−Q_{decay(2)}=2.07113−0.06443 =2.0067 Ah. This pattern may be repeated for all evaluated time intervals (e.g., i: 1→i_{forecasted)}.

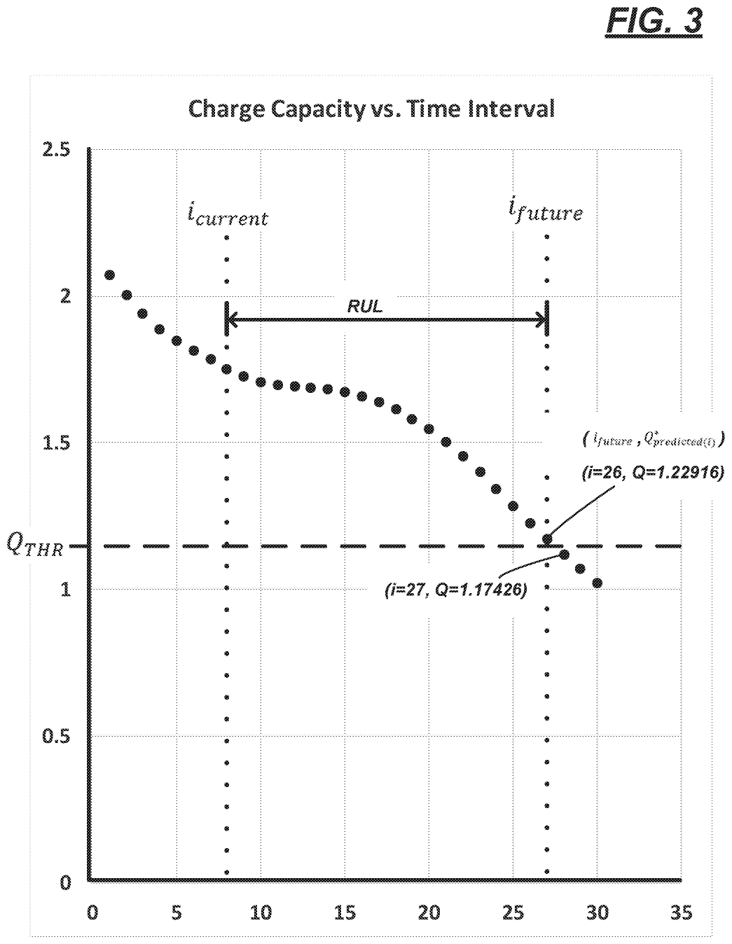

In block 290 which follows, computer 20 may determine the remaining useful life (RUL) of battery 12 by evaluating the remaining time between a current time interval (i_{current}) and a future time interval (i_{future}) that corresponds with a future charge capacity (Q*_{predicted(i)}) which is the last evaluated predicted charge capacity (e.g., in Table II) that is greater than the threshold charge capacity; i.e., Q*_{predicted(i+1)}≤Q_{THR} and Q*_{predicted(i)}>Q_{THR}. See also FIG. 3. To provide an example, consider that Q_{THR}=1.2 Ah. Further, consider that i_{current} may be i₈ (e.g., 8 weeks) and that i_{future} may correspond with i₂₆ (e.g., 26 weeks), as Q*_{predicted(+1)}=1.17426 Ah and Q*_{predicted(i)}=1.22916 Ah. Thus, in block 290, computer 20 may determine Q*_{predicted(i)}, and based on determining Q*_{predicted(i)}, then determine i_{future} that corresponds with Q*_{predicted(i)}.

Since i_{current} may correspond with the last evaluated actual discharge parameter, computer 20 may calculate remaining useful life (RUL) via Equation (11).

RUL=i_{future}−i_{current}. Equation (11).

In the instant example, RUL equals 26−8 or 18 weeks. Of course, this is shown merely to illustrate a technique for determining RUL. Numerous other values may be used and are contemplated herein.

Block 290 may include outputting the RUL (e.g., via a display or other suitable output device), and/or block 290 may include using the RUL value internally within computer 20, within system 10, or the like. Following block 290, the process 200 may loop back to block 220 and continue to execute the process—e.g., in block 230 looking for another trigger or the like. Alternatively, process 200 may end.

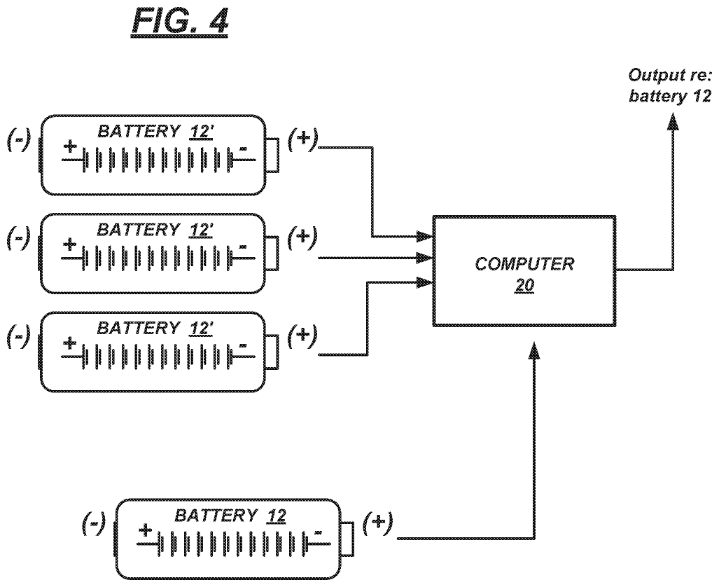

Other techniques for determining RUL may be employed by computer 20 as well. According to one example, computer 20 may monitor a plurality of training batteries 12′ (e.g., in a laboratory environment or the like) (FIG. 4)—e.g., for each of the plurality of training batteries 12′, computer 20 may periodically record actual discharge parameter data, as well as actual charge capacity (Q_{MAX})—until the training batteries 12′ reach a predetermined threshold charge capacity (Q_{THR}). Accordingly, the discharge parameter data may be similar to the data shown in Table I, except that the discharge parameter data may extend for an entirety of the useful life of the training batteries 12′. For example, the actual discharge parameter data may include any combination of the following: discharge quantity parameter, discharge time parameter, quiescent-discharge-time parameter, discharge total-current parameter, or the like.

Using this information (i.e., actual discharge parameter data, as opposed to forecasted discharge parameter data), computer 20 next may determine a unique MLR model (e.g., using Equation (4) or one similar thereto) based on the measured or (measured and calculated) discharge parameter data from each of the training batteries 12′. As more input data may be available, it is contemplated that the MLR model may be more accurate. Thus, instead of predicted degradation (Q_{decay}) and predicted charge capacity (Q_{predicted)}, in this example, computer 20 may calculate and/or record actual degradation and/or actual charge capacity (Q_{MAX}) at a plurality of time intervals (Wᵢ). As multiple training batteries 12′ may be used, the MLR model may be adjusted by averaging charge capacity (Q_{MAX}) data, removing outlier data (e.g., if one of the batteries 12′ was faulty), or the like.

Once the MLR model is developed based on actual discharge data for all values of i, then RUL may be calculated by correlating a time interval that corresponds with a charge capacity (Q_{MAX(i)}) which is the last evaluated charge capacity that is greater than the threshold charge capacity (Q_{THR}); i.e., Q*_{MAX(i+1)}≤Q_{THR} and Q*_{MAX(1)}>Q_{THR}, similar to the process described in process 200. Thereafter, the MLR model developed using the training batteries 12′ may be used with batteries 12 (e.g., used commercially).

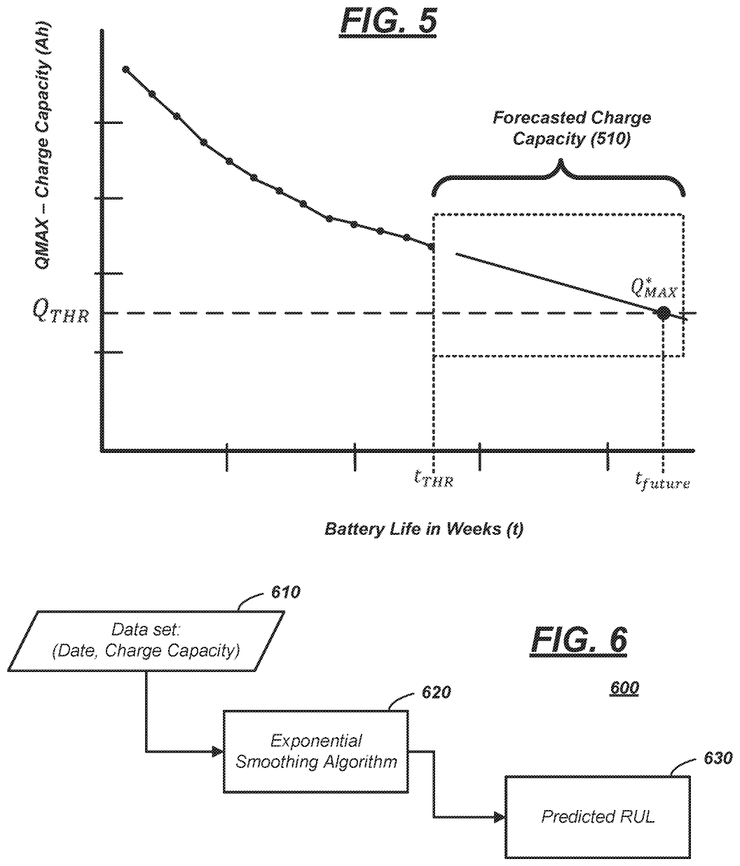

Still other implementations exist. For example, as shown in FIGS. 5-6, computer 20 may measure and/or determine charge capacity (Q_{MAX}) of battery 12 at different time values (t). After a threshold time (t_{THR}) (e.g., after 13 weeks), computer 20 may forecast charge capacity (Q*_{MAX}) that corresponds with a threshold charge capacity (Q_{THR})—e.g., using a forecasting algorithm. The forecasting algorithm may be an exponential smoothing algorithm (e.g., also known as using an exponential window function) such as a Holt-Winter exponential smoothing algorithm, an autoregressive model (e.g., such as Auto-Regressive Integrated Moving Average (ARIMA)), or the like. FIG. 5 is illustrative—it illustrates a plot of charge capacity (Q_{MAX}) vs. time using exemplary data from Table III.

TABLE III

| Date | Charge Capacity (Ah) |
|---|---|
| Nov. 14, 2014 | 2.132590531 |
| Nov. 23, 2014 | 2.066305556 |
| Dec. 1, 2014 | 2.007734722 |
| Dec. 10, 2014 | 1.945593788 |
| Dec. 18, 2014 | 1.894144525 |
| Dec. 27, 2014 | 1.854676389 |
| Jan. 4, 2015 | 1.820709722 |
| Jan. 12, 2015 | 1.7861 |
| Jan. 20, 2015 | 1.747375 |
| Jan. 28, 2015 | 1.734876389 |
| Feb. 5, 2015 | 1.713397222 |
| Feb. 13, 2015 | 1.694088889 |
| Feb. 21, 2015 | 1.674897222 |

FIG. 6 shows a flow diagram—executable by computer 20—illustrating a process 600 for predicting RUL using an exemplary exponential smoothing algorithm (e.g., of course, an ARIMA or the like could be used instead). The process begins with block 610, wherein computer 20 receives as input, a series of time values (e.g., dates and times) and a series of corresponding charge capacities (Q_{MAX} values) of battery 12 (e.g., as shown by example in Table III). Computer 20 then may calculate (block 620)—e.g., using a Holt-Winter exponential smoothing algorithm—a linear projection 510 representing predicted charge capacities (see FIG. 5). Similar to the process described above, computer 20 (in process 600) may determine when the linear projection intersects with a predetermined threshold charge capacity (Q_{THR}), for all values of time (i.e., the corresponding value of Q*_{MAX}). Further, computer 20 may determine a predicted time (t_{future}) which corresponds with Q*_{MAX} (block 630). Thereafter, computer 20 may determine RUL by determining the difference in time via Equation (12).

RUL=t_{future}−t_{THR}. Equation (12).

Thus, this implementation (like that shown in FIG. 2) may use a plurality of previously-measured data (e.g., here previous charge capacity data) and determine future data (e.g., predicted charge capacity data). Like the examples set forth above, this process may be iteratively repeated as well. For example, it may be repeated by computer 20 selected another threshold time (e.g., later in time)—and re-evaluating. Further, aspects of this example may be incorporated with those set forth above. For instance, an exponential smoothing algorithm (e.g., such as Holt-Winter) or the like may be used to determine the forecasted discharge parameters of Table III.

An ability to predict a remaining useful life (RUL) can improve user or operator experience with respect to a machine (having a load) which draws power from the battery. For example, predicting RUL may enable the battery in the machine to be replaced with a new battery at a predetermined, future time—thereby minimizing machine downtime or underperformance.

Thus, a system has been described which permits a computer to receive discharge parameter data from a rechargeable battery. Using the data, the computer can determine a remaining useful life thereof. In at least one example, the computer uses a multiple linear regression computation. In other examples, the computer uses an exponential smoothing algorithm. And in still other implementations, the computer applies data from training batteries to a battery within the system.

In general, the computing systems and/or devices described may employ any of a number of computer operating systems, including, but by no means limited to, versions and/or varieties of the Microsoft® operating system, the Microsoft Windows® operating system, the Unix operating system (e.g., the Solaris® operating system distributed by Oracle Corporation of Redwood Shores, Calif.), the AIX UNIX operating system distributed by International Business Machines of Armonk, N.Y., the Linux operating system, the Mac OSX and iOS operating systems distributed by Apple Inc. of Cupertino, Calif., the BlackBerry OS distributed by Blackberry, Ltd. of Waterloo, Canada, or the Android operating system developed by Google, Inc. and the Open Handset Alliance. Examples of computing devices include, without limitation, a computer server, a computer workstation, a desktop, notebook, laptop, or handheld computer, or some other computing system and/or device.

Computing devices generally include computer-executable instructions, where the instructions may be executable by one or more computing devices such as those listed above. Computer-executable instructions may be compiled or interpreted from computer programs created using a variety of programming languages and/or technologies, including, without limitation, and either alone or in combination, Java™, C, C++, Visual Basic, Java Script, Perl, etc. Some of these applications may be compiled and executed on a virtual machine, such as the Java Virtual Machine, the Dalvik virtual machine, or the like. In general, a processor (e.g., a microprocessor) may receive instructions, e.g., from a memory, a computer-readable medium, etc., and executes these instructions, thereby performing one or more processes, including one or more of the processes described herein. Such instructions and other data may be stored and transmitted using a variety of computer-readable media.

A computer-readable medium (also referred to as a processor-readable medium) includes any non-transitory (e.g., tangible) medium that participates in providing data (e.g., instructions) that may be read by a computer (e.g., by a processor of a computer). Such a medium may take many forms, including, but not limited to, non-volatile media and volatile media. Non-volatile media may include, for example, optical or magnetic disks and other persistent memory. Volatile media may include, for example, dynamic random-access memory (DRAM), which typically constitutes a main memory. Such instructions may be transmitted by one or more transmission media, including coaxial cables, copper wire and fiber optics, including the wires that comprise a system bus coupled to a processor of a computer. Common forms of computer-readable media include, for example, a floppy disk, a flexible disk, hard disk, magnetic tape, any other magnetic medium, a CD-ROM, DVD, any other optical medium, punch cards, paper tape, any other physical medium with patterns of holes, a RAM, a PROM, an EPROM, a FLASH-EEPROM, any other memory chip or cartridge, or any other medium from which a computer can read.

Databases, data repositories or other data stores described herein may include various kinds of mechanisms for storing, accessing, and retrieving various kinds of data, including a hierarchical database, a set of files in a file system, an application database in a proprietary format, a relational database management system (RDBMS), etc. Each such data store is generally included within a computing device employing a computer operating system such as one of those mentioned above, and are accessed via a network in any one or more of a variety of manners. A file system may be accessible from a computer operating system, and may include files stored in various formats. An RDBMS generally employs the Structured Query Language (SQL) in addition to a language for creating, storing, editing, and executing stored procedures, such as the PL/SQL language mentioned above.

The disclosure has been described in an illustrative manner, and it is to be understood that the terminology which has been used is intended to be in the nature of words of description rather than of limitation. Many modifications and variations of the present disclosure are possible in light of the above teachings, and the disclosure may be practiced otherwise than as specifically described.

1. A method, comprising:
determining, for a battery, at least two discharge parameters from among a plurality of discharge parameters, wherein the plurality includes: a discharge quantity parameter, a discharge time parameter, a discharge rest-time parameter, and a discharge total-current parameter;
using the at least two discharge parameters to derive a multiple linear regression (MLR) model representing capacity degradation (Q_{decay}); and
using the model, calculating a remaining useful life (RUL) of the battery.

2. The method of claim 1, further comprising: receiving actual discharge parameter data for a portion of a useful life of the battery; and calculating forecasted discharge parameter data using the actual discharge parameter data, wherein the model is based on the forecasted discharge parameter data.

3. The method of claim 2, further comprising: using a single linear regression or an exponential smoothing algorithm to determine the forecasted discharge parameter data.

4. The method of claim 3, further comprising: using the forecasted discharge parameter data to determine a predicted degradation of the battery at time interval (Wᵢ).

5. The method of claim 1, further comprising: using the model, determining a plurality of predicted charge capacities (Q_{predicted(i)}) for a plurality of corresponding predicted degradations (Q_{decay(i)}).

6. The method of claim 5, further comprising: determining the RUL by comparing a threshold charge capacity (Q_{THR}) with the plurality of predicted charge capacities (Q_{predicted(i)}).

7. The method of claim 6, further comprising: determining the RUL when one of the plurality of predicted charge capacities (Q*_{predicted(i)}) is greater than the threshold charge capacity (Q_{THR}) and a subsequent of the predicted charge capacities (Q*_{predicted(i+1)}) is less than or equal to the threshold charge capacity (Q*_{predicted(i)}>Q_{THR} and Q*_{predicted(i+1)}≤Q_{THR}).

8. The method of claim 7, wherein RUL comprises a difference between a time of calculation (i_{current}) and a time (i_{future}) that corresponds with Q*_{predicted(i)}.

9. The method of claim 1, wherein the model is based on each of the plurality of discharge parameters.

10. The method of claim 1, wherein the discharge quantity parameter is a quantity (k) of discharge events during a given time interval (Wᵢ).

11. The method of claim 1, wherein the discharge time parameter is an average duration (t_{DE}) of all discharge events for a given time interval (Wᵢ).

12. The method of claim 1, wherein the quiescent-discharge-time parameter is an average duration (t_{QE}) of quiescent events for a given time interval (Wᵢ).

13. The method of claim 1, wherein the discharge total-current parameter is a magnitude of total electrical current (I_{DE}) during a discharge event over a given time interval (Wᵢ).

14. The method of claim 1, wherein the model includes: Q_{decay}=β₀+β₁*Xₖβ₂* X_{DE}+β₃*X_{QE}β₄*X_{I}, wherein Xₖ, X_{DE}, X_{QE}, and X_{I} respectively are variables representing the discharge quantity parameter, the discharge time parameter, the quiescent-discharge-time parameter, and the discharge total-current parameter, wherein β₀, β₁, β₂, β₃, and β₄, are calculated constants.

15. The method of claim 1, wherein the battery is a training battery.

16. The method of claim 2, further comprising: using the model to determine the RUL of another battery before its useful life expires.

17. A method, comprising:
for a battery, using a plurality of previously-measured charge capacities (Q_{MAX}) and a plurality of corresponding time values, calculating a forecasted charge capacity; and
using a threshold charge capacity (Q_{THR}), determining a remaining useful life (RUL) of the battery based on the forecasted charge capacity,
wherein the calculation includes using at least one of an exponential smoothing algorithm or an autoregressive model.

18. The method of claim 17, wherein the algorithm is a Holt-Winter exponential smoothing algorithm, wherein the model comprises an Autoregressive Integrated Moving Average (ARIMA).

19. A method, comprising:
using at least a discharge quantity parameter and a discharge total-current parameter, deriving a multiple linear regression (MLR) model to predict capacity degradation of a rechargeable battery;
determining forecasted discharge parameters for each of the discharge quantity and discharge total-current parameters;
determining predicted degradation (Q_{decay}) of the battery using the model and the forecasted discharge parameters; and
based on the predicted degradation, determining a remaining useful life (RUL) of the battery by comparing the degradation with a threshold charge capacity (Q_{THR}).

20. The method of claim 19, further comprising: also using a discharge time parameter and a quiescent-discharge-time parameter to derive the model; and determining the forecasted discharge parameters also using the discharge time and quiescent-discharge-time parameters.
